(19) United States
(12) Patent Application Publication
(10) Pub. No.: US 2021/0222064 A1
(43) Pub. Date: Jul. 22, 2021

(54) QUANTUM DOT STRUCTURE AND MANUFACTURING METHOD THEREOF, OPTICAL FILM AND MANUFACTURING METHOD THEREOF, DISPLAY DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventor: Aidi ZHANG, Beijing (CN)

(21) Appl. No.: 16/633,806

(22) PCT Filed: Jan. 18, 2019
(86) PCT No.: PCT/CN2019/072404

§ 371 Date: Jan. 24, 2020

(51) Int. Cl. C09K 11/88; B05D 5/06; B05D 7/24; B05D 3/02; C09K 11/56; C09K 11/02

(52) U.S. Cl. CPC C09K 11/883; B05D 5/06; B05D 7/24; B82Y 20/00; C09K 11/565; C09K 11/02; B05D 3/0254

(57) ABSTRACT

A quantum dot structure and a manufacturing method thereof, an optical film and a manufacturing method thereof, and a display device. The quantum dot structure includes: a quantum dot including a quantum dot body and a quantum dot surface layer; and an oxide layer on a surface of the quantum dot to partly cover the surface of the quantum dot. The quantum dot surface layer includes a negative ion, and the oxide layer is combined with the negative ion through a coordinate bond.

### TECHNICAL FIELD

Embodiments of the present disclosure relate to a quantum dot structure and a manufacturing method thereof, an optical film and a manufacturing method thereof, and a display device.

### BACKGROUND

Quantum dot is a kind of Nano-scaled semiconductor material. By applying the Nano-scaled semiconductor materials with a certain electric field or light pressure, they will emit light with a certain frequency. Furthermore, the frequency of the light emitted by the quantum dot will be changed with a change of dimension of such semiconductor. As a result, a color of the light emitted by the Nano-scaled semiconductor may be controlled just by adjusting the dimension of such Nano-scaled semiconductor. Moreover, because the quantum dot possesses excellent physicochemical and optical properties, e.g., wide range of excitation spectrum, narrow range of fluorescence emission spectrum and the like, it has gained extensive studies, attentions and applications from many fields including photodiode, solar cell, bio-analysis and bio-labeling, etc.

### SUMMARY

At least one embodiment of the present disclosure provides a quantum dot structure, including: a quantum dot including a quantum dot body and a quantum dot surface layer; and an oxide layer on a surface of the quantum dot, the oxide layer partly covers the surface of the quantum dot. The quantum dot surface layer includes a negative ion, and the oxide layer is combined with the negative ion through a coordinate bond.

For example, in the quantum dot structure provided by an embodiment of the present disclosure, the oxide layer includes a metal ion.

For example, in the quantum dot structure provided by an embodiment of the present disclosure, the metal ion includes at least one selected from the group consisting of cadmium (Cd) ion, nickel (Ni) ion, zinc (Zn) ion, aluminum (Al) ion, and rare earth ion.

For example, in the quantum dot structure provided by an embodiment of the present disclosure, one negative ion is combined with one metal ion.

For example, in the quantum dot structure provided by an embodiment of the present disclosure, a thickness of the oxide layer is in a range of 0.3 nm-1 nm.

For example, in the quantum dot structure provided by an embodiment of the present disclosure, the quantum dot surface layer further includes a positive ion; and the positive ion and the negative ion are regularly arranged on the quantum dot surface layer.

For example, in the quantum dot structure provided by an embodiment of the present disclosure, the oxide layer exposes the positive ion.

For example, the quantum dot structure provided by an embodiment of the present disclosure further includes: a surface ligand on the positive ion of the quantum dot and on the oxide layer.

For example, in the quantum dot structure provided by an embodiment of the present disclosure, a diameter of the quantum dot is in a range of 3 nm-15 nm.

For example, in the quantum dot structure provided by an embodiment of the present disclosure, the quantum dot includes one or more selected from the group consisting of a core quantum dot, a core/shell quantum dot, a core/shell/shell quantum dot, and a core/gradient shell layer quantum dot.

At least one embodiment of the present disclosure further provides an optical film including the quantum dot structure described in any one of the foregoing embodiments.

At least one embodiment of the present disclosure further provides a display device including a light-emitting region; the light-emitting region is provided with the quantum dot structure described in any one of the foregoing embodiments or the optical film described above.

At least one embodiment of the present disclosure further provides a manufacturing method of a quantum dot structure, including: providing a quantum dot, the quantum dot including a quantum dot body and a quantum dot surface layer; and forming an oxide layer on a surface of the quantum dot, the oxide layer partly covers the surface of the quantum dot. The quantum dot surface layer includes a negative ion, and the oxide layer is combined with the negative ion through a coordinate bond.

For example, in the manufacturing method of the quantum dot structure provided by an embodiment of the present disclosure, forming the oxide layer on the surface of the quantum dot to partly cover the surface of the quantum dot includes: mixing a solution of the quantum dot with a solution containing a metal ion; attaching the metal ion in the solution containing the metal ion onto the surface of the quantum dot; introducing oxygen gas and driving the metal ion in the solution containing the metal ion to be oxidized on the surface of the quantum dot and to generate an oxide molecule; and forming the oxide layer on the surface of the quantum dot by controlling an amount of the solution containing the metal ion and controlling a reaction time.

For example, in the manufacturing method of the quantum dot structure provided by an embodiment of the present disclosure, attaching the metal ion in the solution containing the metal ion onto the surface of the quantum dot includes: attaching the metal ion in the solution containing the metal ion onto the surface of the quantum dot by at least one of a heating process, a stirring process, and an ultrasonic process.

For example, in the manufacturing method of the quantum dot structure provided by an embodiment of the present disclosure, attaching the metal ion in the solution containing the metal ion to be attached onto the surface of the quantum dot by at least one of the heating process, the stirring process, and the ultrasonic process includes: performing the heating process and the stirring process to a mixed solution of the solution of the quantum dot and the solution containing the metal ion to cause the metal ion in the solution containing the metal ion to be attached onto the surface of the quantum dot; a temperature of the heating process is 200° C.-300° C., and a revolving speed of the stirring process is in a range of 300 rpm-1000 rpm.

For example, in the manufacturing method of the quantum dot structure provided by an embodiment of the present disclosure, the solution containing metal ion includes a long chain fatty acid salt of at least one selected from the group consisting of cadmium (Cd) ion, nickel (Ni) ion, zinc (Zn) ion, aluminum (Al) ion, and rare earth ion.

At least one embodiment of the present disclosure further provides a manufacturing method of an optical film, including: manufacturing at least one of a red color quantum dot, a green color quantum dot and a blue color quantum dot by adopting the manufacturing method of the quantum dot structure described in any one of the foregoing embodiments; mixing a solution of at least one of the red color quantum dot as manufactured, the green color quantum dot as manufactured, and the blue color quantum dot as manufactured with a polymer solution, and pouring the mixed solution onto a polymeride substrate; and curing the polymer solution to form the optical film.

### BRIEF DESCRIPTION OF THE DRAWINGS

In order to clearly illustrate the technical solutions of the embodiments of the disclosure, the drawings of the embodiments will be briefly described in the following; it is obvious that the described drawings are only related to some embodiments of the disclosure and thus are not limitative to the disclosure.

FIG. 1A is a schematic view of a quantum dot;

FIG. 1B is a schematic view illustrating a surface atom arrangement on a cross section of a quantum dot structure provided by an embodiment of the present disclosure;

FIG. 2 is a schematic view illustrating a surface atom arrangement on a cross section of another quantum dot structure provided by an embodiment of the present disclosure;

FIG. 3 is a schematic view of an optical film provided by an embodiment of the present disclosure;

FIG. 4 is a schematic view of a display device provided by an embodiment of the present disclosure;

FIG. 5 is a flow chart of a manufacturing method of a quantum dot structure provided by an embodiment of the present disclosure;

FIG. 6 is a schematic view illustrating steps of a manufacturing method of a quantum dot structure provided by an embodiment of the present disclosure; and

FIG. 7 is a schematic view illustrating steps of a manufacturing method of an optical film provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

Generally, a surface of a core quantum dot manufactured by adopting a wet chemical method is only wrapped with a layer of organic ligands, which results in a poor fluorescence quantum yield of the core quantum dot. Under continuous illumination, a surface oxidation is easily occurred for the core quantum dot and leads to a rapid drop of fluorescence. Therefore, upon the quantum dot being applied in the field of photoelectric devices (e.g., photodiode and solid state light source, etc.), how to maintain an initial fluorescence intensity of the quantum dot becomes one important challenge. It should be explained that, the above-described fluorescence quantum yield is an important parameter for assessing the performance of the quantum dot. The fluorescence quantum yield is just a ratio of the number of photons of fluorescence light emitted by the quantum dot after light absorption to the number of photons of excitation light absorbed by the quantum dot. Under normal conditions, a value of the fluorescence quantum yield is always smaller than 1; a greater value for the fluorescence quantum yield indicates a stronger fluorescence of a substance, while the fluorescence quantum yield of a substance free from fluorescence is equal to or extremely close to zero.

At present, the existing chemosynthesis method has successively introduced different inorganic shell layers to the core quantum dot, for example, CdSe/CdS core/shell quantum dot, CdSe/ZnS core/shell quantum dot, InP/ZnS core/shell quantum dot, CdSe/CdS/ZnS core/shell/shell quantum dot, and the like. In such kind of quantum dot with a core/shell structure, the core quantum dot is wrapped by a shell layer with wider band gap, and the core/shell structure can improve the fluorescence quantum yield of the quantum dot to a certain extent. However, there are issues such as lattice mismatch and lattice strain existed between a material of core quantum dot and a material of shell layer for a core/shell structure with core-shell heterogeneous; after the core quantum dot is wrapped by a shell layer with a certain thickness, the fluorescence quantum yield of the quantum dot begins to be reduced again, and a grain size of the quantum dot represents heterogeneity which is manifested as defections such as a widened fluorescence emission peak.

On the other aspect, quantum dot with gradient alloy structure is a recently developed quantum dot with higher quantum yield. In the quantum dot with gradient alloy structure, an outer side of the core quantum dot is wrapped by a layer of shell layer with gradient alloy. Elements of this shell layer are gradually varied from the inside to the most outside so as to appear as being gradient, thereby avoiding a separation of interfaces of the core quantum dot and the shell layer. For example, an outer side of a CdSe core quantum dot may be wrapped by a CdSeS shell layer with gradient alloy so as to prepare a CdSe/CdSeS quantum dot. The quantum dot with gradient alloy structure (also referred to as quantum dot with core/alloy shell layer structure) can effectively prevent from issues such as lattice mismatch and lattice strain resulted by a difference in lattice constant between different materials. However, because a negative ion of an outermost layer of the quantum dot with gradient alloy structure is usually constituted by Sulphur (S), Selenium (Se), Tellurium (Te), Phosphorus (P) or the like, an oxidation reaction is easily occurred to reduce the fluorescence efficiency of the quantum dot. Therefore, the quantum dot with gradient alloy structure will not permanently eliminate the risks of surface oxidation and fluorescence quenching of the quantum dot.

Embodiments of the present disclosure provide a quantum dot structure and a manufacturing method thereof, an optical film, and a display device. The quantum dot structure includes: a quantum dot including a quantum dot body and a quantum dot surface layer; and an oxide layer on a surface of the quantum dot to partly cover the surface of the quantum dot. The quantum dot surface layer includes a negative ion, and the oxide layer is combined with the negative ion through a coordinate bond. The quantum dot structure provides an oxide layer which partly covers the surface of the quantum dot and is combined with the negative ion of the quantum dot surface layer through a coordinate bond, on the surface of the quantum dot, so as to protect the negative ion of the quantum dot surface layer, thereby preventing the negative ion of the quantum dot surface layer from oxidation. In this way, the quantum dot structure can improve an optical stability and a chemical stability of the quantum dot under the preconditions that the optical property and surface ligand of the quantum dot will not be changed, and can also maintain an initial fluorescence quantum yield of the quantum dot.

Hereinafter, a quantum dot structure and a manufacturing method thereof, an optical film and a manufacturing method thereof, and a display device provided by embodiments of the present disclosure will be described in more details in conjunction with the drawings.

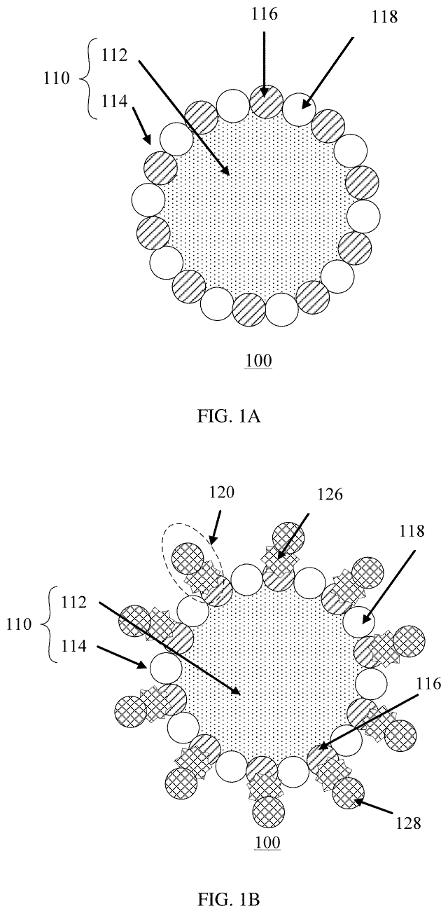

An embodiment of the present disclosure provides a quantum dot structure. FIG. 1A is a schematic view of a quantum dot; FIG. 1B is a schematic view of a quantum dot structure provided by an embodiment of the present disclosure. As illustrated in FIG. 1A, the quantum dot 110 includes a quantum dot body 112 and a quantum dot surface layer 114; the quantum dot surface layer 114 includes a negative ion 116 and a positive ion 118. For example, the negative ion 116 and the positive ion 118 are regularly arranged on the surface of the quantum dot 110, for example, being alternately arranged at intervals. As illustrated in FIG. 1B, the quantum dot structure 100 includes a quantum dot 110 and an oxide layer 120. The oxide layer 120 is located at the surface of the quantum dot 110, and partly covers the surface of the quantum dot 110; the oxide layer 120 is combined with the negative ion 116 through a coordinate bond. As illustrated in FIG. 1A and FIG. 1B, the quantum dot structure illustrated in FIG. 1B is equivalent to introducing an oxide layer 120 on the quantum dot 110 illustrated in FIG. 1A. For example, the negative ion 116 may be a Sulphur (S) ion, a Selenium (Se) ion, a Tellurium (Te) ion, a phosphorus (P) ion, or the like. It should be explained that, a structural determination and a surface atomic analysis of the above-described structure may be performed through a high resolution transmission electron microscopy (HRTEM), an energy dispersive spectrometer (EDS) and an electron energy lose spectroscopy (EELS); moreover, the above-described “partly cover” refers to that the oxide layer does not cover an entire surface of the quantum dot.

In the quantum dot structure provided by the preset embodiment, by providing an oxide layer that partly covers the surface of the quantum dot and that is combined with the negative ion of the quantum dot surface layer through a coordinate bond, on the surface of the quantum dot, it can protect the negative ion (e.g., S ion, Se ion, Te ion, P ion or the like) of the quantum dot surface layer, so as to prevent the negative ion of the quantum dot surface layer from oxidation, to passivate the surface of the quantum dot, and to isolate the quantum dot from external moisture and oxygen. In this way, the quantum dot structure can improve the optical stability and the chemical stability of the quantum dot under the preconditions that the optical property and surface ligand of the quantum dot will not be changed. During long-term usage of the quantum dot structure, for example, during continuous illumination on the quantum dot structure for emitting fluorescent light, the quantum dot structure can maintain the initial fluorescence quantum yield of the quantum dot. On the other aspect, the oxide layer can also occupy a surface dangling bond of the negative ion (e.g., S, Se and the like) of the quantum dot surface layer, and eliminate a surface defect of the quantum dot, so as to further improve the fluorescence quantum yield of the quantum dot. It should be explained that, because the negative ion of the quantum dot surface layer carries additional electrons and hence possesses electronegativity, it is easily to be oxidized to lose electrons; while the positive ion of the quantum dot surface layer is not easily to be oxidized because it has lost the electrons.

For example, in some examples, the oxide layer includes a metal ion, e.g., at least one selected from the group consisting of cadmium (Cd), nickel (Ni), zinc (Zn), aluminum (Al) and rare earth ion, so as to be coordinated with the negative ion (e.g., S, Se, Te, P ion or the like) of the quantum dot surface layer. Moreover, an oxide layer formed by adopting the above-described metal ion can prevent from quenching the fluorescent light of the quantum dot.

For example, in some examples, when the metal ion of the oxide layer is a rare earth ion (e.g., lanthanum ion, cerium ion and rubidium ion), the earth ion can also modulate a confinement ability of carriers, so as to change a forbidden band width and a fluorescence emission peak of the quantum dot.

For example, in some examples, as illustrated in FIG. 1B, the oxide layer discontinuously covers the surface of the quantum dot. Because the oxide layer is only combined with the negative ion of the quantum dot surface layer through the coordinate bond to merely half cover the quantum dot surface layer, e.g., merely covering one half of ions of the quantum dot surface layer, the oxide layer is discontinuous, that is, the oxide layer is provided with a plurality of openings or includes a plurality of island-shaped oxides.

For example, in some examples, as illustrated in FIG. 1B, one negative ion 116 is combined with one metal ion 126. One metal ion 126 is combined with one oxygen atom 128. In such case, a thickness of the oxide layer is in a range of 0.3 nm-1 nm. The oxide layer provided by the present example is consisting of two atoms, thus the thickness thereof is in a range of 0.3 nm-1 nm. In such case, the oxide layer possesses properties including transparency, densification and the like, so as to effectively isolate the quantum dot from external environment, to prevent the negative ion from contacting with the external environment, and hence to increase a service life of the quantum dot. For example, in some examples, as illustrated in FIG. 1B, the surface layer of the quantum dot 110 includes a positive ion 118; the positive ion 118 and the negative ion 116 are regularly arranged on the quantum dot surface layer. The above-described “regularly arranged” refers to that the positive ion and the negative ion are uniformly distributed on the quantum dot surface layer. In such case, because the oxide layer combines with the negative ion of the quantum dot surface layer through a coordinate bond, the oxide layer is also uniform. That is to say, when the oxide layer includes a plurality of openings, the plurality of openings are uniformly distributed (e.g., being in one-to-one correspondence with the positive ions of the quantum dot surface layer); when the oxide layer includes a plurality of island-shaped oxides, the plurality of island-shaped oxides are uniformly distributed (e.g., being in one-to-one correspondence with the negative ions of the quantum dot surface layer).

For example, in some examples, the oxide layer exposes the positive ion. That is to say, when the oxide layer includes a plurality of openings, the plurality of openings are in one-to-one correspondence with the positive ions of the quantum dot surface layer so as to expose the positive ions to the external environment; when the oxide layer includes a plurality of island-shaped oxides, intervals of the plurality of island-shaped oxides expose the positive ions to the external environment.

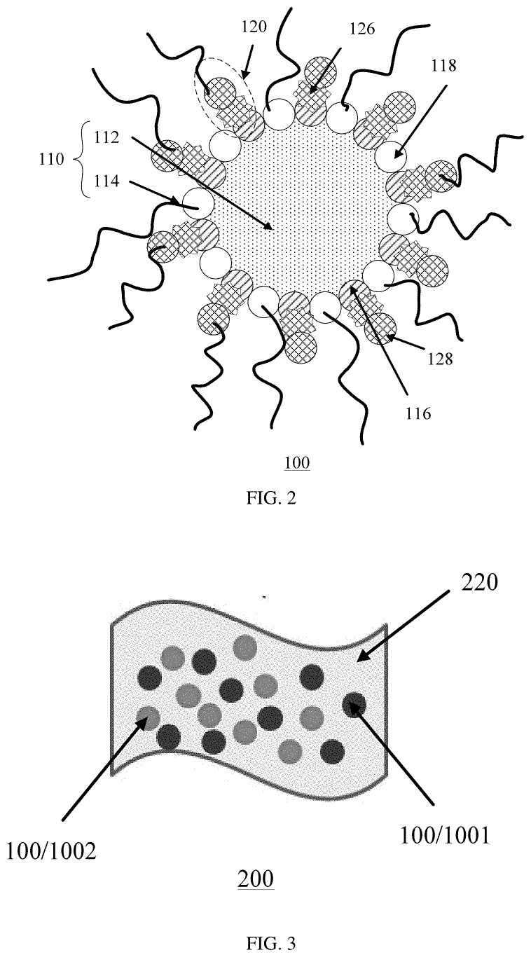

FIG. 2 illustrates another quantum dot structure provided by an embodiment of the present disclosure. As illustrated in FIG. 2, the quantum dot structure further includes surface ligands 130 on the positive ion 118 of the surface layer of the quantum dot 110 and on the oxide layer 120. Because the oxide layer 120 discontinuously covers the surface layer of the quantum dot 110, a part of the surface ligands can pass through the oxide layer 120 and extend to the outside of the oxide layer 120, that is, one side away from the quantum dot 110, and another part of the surface ligands 130 can be transferred onto the oxide layer 120. As a result, the quantum dot structure may not change the surface ligands, and hence may not influence an application range and a function of the quantum dot. It should be explained that, the surface ligand on one aspect can increase a solubility of the quantum dot structure in the solution which facilitates dispersing the quantum dot structure in the solution, and on the other aspect can also eliminate the surface defect of the quantum dot, for example, the dangling bond on the surface of the quantum dot, which can further improve the fluorescence quantum yield of the quantum dot.

For example, in some examples, a diameter of the quantum dot is in a range of 3 nm-15 nm.

For example, in some examples, the quantum dot includes one or more selected from the group consisting of a core quantum dot, a core/shell quantum dot, a core/shell/shell quantum dot and a core/gradient shell layer quantum dot. Because the oxide layer introduced by the quantum dot structure will not result in any negative influence to the property and function of the quantum dot per se, the quantum dot structure may possess the property and function of the quantum dot included therein. For example, when the quantum dot is a core/shell quantum dot or a core/shell/shell quantum dot, the core quantum dot is wrapped by a shell layer with wider band gap, and the core/shell structure can improve the fluorescence quantum yield of the quantum dot to a certain extent. For example, when the quantum dot is a shell/gradient shell layer quantum dot, it can effectively prevent from the issues such as lattice mismatch and lattice strain resulted by a difference in lattice constant between different materials.

For example, in some examples, the quantum dot may be one or more selected from the group consisting of CdSe/CdS/ZnS quantum dot, CdTe quantum dot, CdS quantum dot, CdSe quantum dot, ZnSe quantum dot, InP quantum dot, CuInS quantum dot, CulnSe quantum dot, PbS quantum dot, CdS/ZnS quantum dot, CdSe/ZnS quantum dot, CdSe/ZnSeS quantum dot, CdSe/CdS quantum dot, ZnSe/ZnS quantum dot, InP/ZnS quantum dot, CuInS/ZnS quantum dot, (Zn)CuInS/ZnS quantum dot, (Mn)CuInS/ZnS quantum dot, AgInS/ZnS quantum dot, (Zn)AgInS/ZnS quantum dot, CulnSe/ZnS quantum dot, CuInSeS/ZnS quantum dot, PbS/ZnS quantum dot, CsPbCl₃/ZnS quantum dot, CsPbBr₃/ZnS quantum dot, CsPbI₃/ZnS quantum dot, organic and inorganic perovskite quantum dot (MAPbX₃, MA=CH₃NH₃, X═Cl, Br, I), all-inorganic perovskite quantum dot (CsPbX₃, X═Cl, Br, I), carbon quantum dot and silicon quantum dot.

For example, in some examples, the quantum dot structure provided by the embodiments of the present disclosure may be applied in the fields such as biological analysis, bioimaging, photovoltaic conversion, and gene and drug carrier therapy. For example, the quantum dot structure may be used for manufacturing a quantum dot LED, a quantum dot solar cell, a semiconductor device, a display device, a quantum dot display device, a light-emitting device, a magnetic and fluorescence induction device, a biosensor, a nuclear magnetic resonance (NMR) contrast agent and an imaging agent, etc.

An embodiment of the present disclosure provides an optical film. FIG. 3 is a schematic view of an optical film provided by an embodiment of the present disclosure. As illustrated in FIG. 3, the optical film 200 may include the quantum dot structure 100 in the foregoing embodiments.

In the optical film provided by the present embodiment, by providing an oxide layer that partly covers the surface of the quantum dot and that is combined with the negative ion of the quantum dot surface layer through a coordinate bond, on the surface of the quantum dot, it can protect the negative ion (e.g., S ion, Se ion, Te ion, P ion or the like) of the quantum dot surface layer, so as to prevent the negative ion of the quantum dot surface layer from oxidation, to passivate the surface of the quantum dot, and to isolate the quantum dot from external moisture and oxygen. In this way, the quantum dot structure can improve the optical stability and the chemical stability of the quantum dot under the preconditions that the optical property and surface ligand of the quantum dot will not be changed, and hence also improve the optical stability and the chemical stability of the optical film. During long-term usage of the optical film, for example, during continuous illumination on the optical film for emitting fluorescent light, the optical film can maintain the initial fluorescence quantum yield of the quantum dot. On the other aspect, the oxide layer can also occupy a surface dangling bond of the negative ion (e.g., S, Se and the like) of the quantum dot surface layer, and eliminate a surface defect of the quantum dot, so as to further improve the fluorescence quantum yield of the quantum dot.

For example, in some examples, the quantum dot structure 100 in the optical film 200 may include a red light quantum dot structure 1001 emitting red fluorescence light and a green light quantum dot structure 1002 emitting green fluorescence light.

For example, in some examples, the optical film may be used for manufacturing a quantum dot color enhancement layer in a display device. Of course, the embodiments of the present disclosure include such case but are not limited thereto, and the optical film may also be used in a light-emitting device, a lighting device and the like.

It should be explained that, although the embodiments of the present disclosure provide an optical film including the above-described quantum dot structure, it's not intended to indicate that the quantum dot structure merely can be applied in the form of optical film. The quantum dot structure may also be used by way of printing, coating and the like.

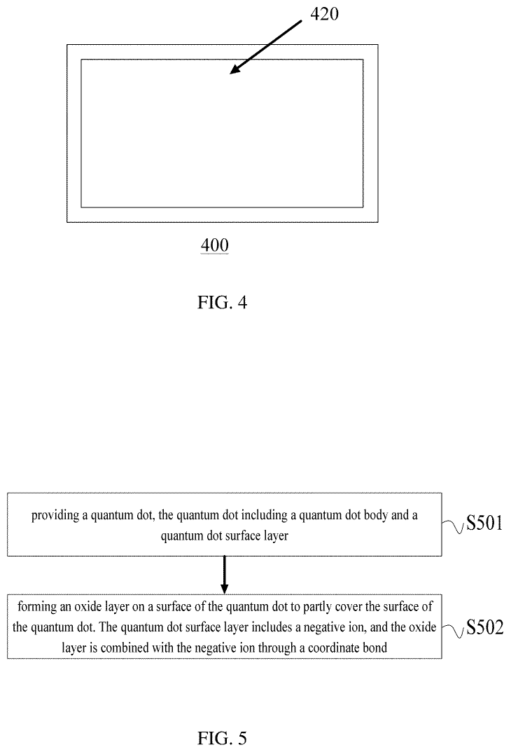

An embodiment of the present disclosure provides a display device. FIG. 4 is a schematic view of a display device provided by an embodiment of the present disclosure. As illustrated in FIG. 4, the display device 400 includes a light-emitting region 420 which is provided with the above-described quantum dot structure 100 or the above-described optical film 200. In this way, the display device 400 possesses better stability and longer service life.

An embodiment of the present disclosure provides a manufacturing method of a quantum dot structure. FIG. 5 illustrates a manufacturing method of a quantum dot structure provided by an embodiment of the present disclosure. As illustrated in FIG. 5, the manufacturing method of the quantum dot structure includes the following steps S501-S502.

Step S501, providing a quantum dot, the quantum dot including a quantum dot body and a quantum dot surface layer.

Step S502, forming an oxide layer on a surface of the quantum dot to partly cover the surface of the quantum dot. The quantum dot surface layer includes a negative ion, and the oxide layer is combined with the negative ion through a coordinate bond.

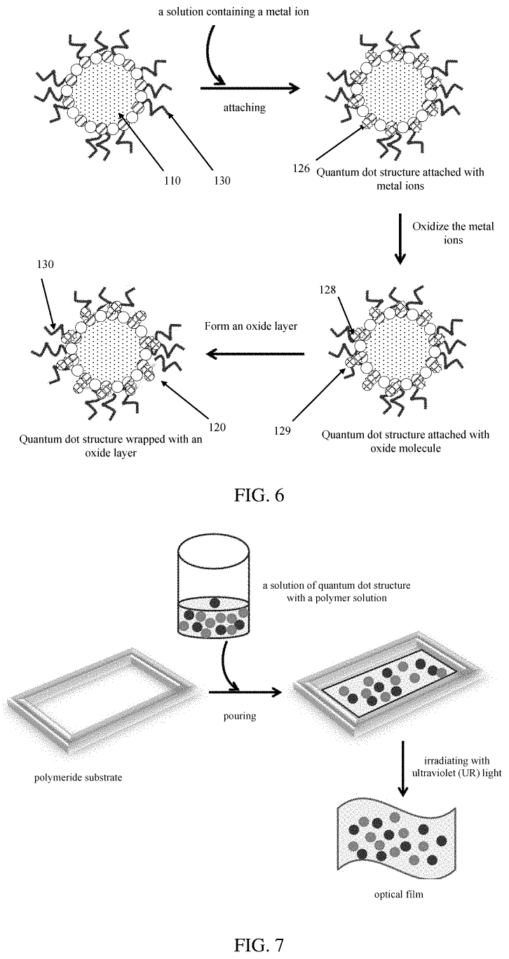

FIG. 6 is a schematic view illustrating steps of a manufacturing method of a quantum dot structure provided by an embodiment of the present disclosure. Forming an oxide layer on a surface of the quantum dot to partly cover the surface of the quantum dot may include the following steps S601-S603.

Step S601, mixing a solution of quantum dot with a solution containing a metal ion.

For example, the quantum dot may be one or more selected from the group consisting of CdSe/CdS/ZnS quantum dot, CdTe quantum dot, CdS quantum dot, CdSe quantum dot, ZnSe quantum dot, InP quantum dot, CuInS quantum dot, CulnSe quantum dot, PbS quantum dot, CdS/ZnS quantum dot, CdSe/ZnS quantum dot, CdSe/ZnSeS quantum dot, CdSe/CdS quantum dot, ZnSe/ZnS quantum dot, InP/ZnS quantum dot, CuInS/ZnS quantum dot, (Zn)CuInS/ZnS quantum dot, (Mn)CuInS/ZnS quantum dot, AgInS/ZnS quantum dot, (Zn)AgInS/ZnS quantum dot, CulnSe/ZnS quantum dot, CuInSeS/ZnS quantum dot, PbS/ZnS quantum dot, CsPbCl₃/ZnS quantum dot, CsPbBr₃/ZnS quantum dot, CsPbI₃/ZnS quantum dot, organic and inorganic perovskite quantum dot (MAPbX₃, MA=CH₃NH₃, X═Cl, Br, I), all-inorganic perovskite quantum dot (CsPbX₃, X═Cl, Br, I), carbon quantum dot and silicon quantum dot.

For example, the oxide precursor solution may be a solution of long chain fatty acid salt such as oleate, stearate, and myristate. For example, the oxide precursor solution may be cadmium salt of long chain fatty acid (e.g., cadmium stearate, cadmium nutmeg and the like), nickel salt of long chain fatty acid, gadolinium salt of long chain fatty acid, or salt of rear earth ion.

For example, the solution of quantum dot may be an n-hexane solution of CdSe/CdS/ZnS quantum dot, and the oxide precursor solution may be a solution of long fatty acid cadmium (corresponding to the long fatty acid salt of the oxide to be formed). At this time, 10⁻⁵ mmol n-hexane solution of CdSe/CdS/ZnS quantum dot and 1 mmol solution of cadmium oleate may be added into a three-necked flask containing 5 mL octadecene solution, to mix the solution of CdSe/CdS/ZnS quantum dot with the cadmium oleate (the oxide precursor solution). It should be explained that, the above-mentioned 5 mL octadecene solution serves as a solvent, because the octadecene has relatively higher boiling point which can maintain the quantum dot to be dissolved at high temperature.

For example, a catalyst, e.g., 2 mL n-octylamine, may be further added into the above-described mixed solution to accelerate the reaction.

For example, the above-described reaction system may also be vacuum-pumped at 120° C. for 60 min.

Step S602, attaching the metal ion in the solution (i.e., the oxide precursor solution) containing the metal ion onto the surface of the quantum dot.

For example, as illustrated in FIG. 6, because the negative ion and the positive ion carry opposite charges, they may be attracted to each other. As a result, the positive ion 126 in the oxide precursor solution may be attached onto the outer side of the negative ion 116 of the surface layer of the quantum dot 110, firstly.

Step S603, introducing oxygen gas and driving the positive ion in the oxide precursor solution to be oxidized on the surface of the quantum dot and to generate an oxide molecule; and forming an oxide layer on the surface of the quantum dot by controlling an amount of the oxide precursor solution and controlling a reaction time.

For example, as illustrated in FIG. 6, the positive ion 126 that is attached onto the negative ion of the surface layer of the quantum dot 110 is oxidized by an oxygen molecule 128 and generates an oxide molecule 129.

For example, a temperature of the above-described reaction system may be raised to 200° C.-300° C., and the reaction system may be heated for 30 min-120 min and aerated with an appropriate amount of oxygen gas under a magnetic stirring operation at 300 rpm-1000 rpm, so that the positive ion (metal ion) in the oxide precursor solution is oxidized on the quantum dot surface layer and generates an oxide layer 120. It should be explained that, during this process, a long chain fatty acid radical in the oxide precursor solution can be attached onto the surface of the quantum dot and formed into another type of surface ligand.

In the manufacturing method of the quantum dot structure provided by the present embodiment, the solution of quantum dot and the oxide precursor solution are mixed firstly, and the metal ion in the oxide precursor solution is attached onto the quantum dot surface layer (e.g., it may be a surface layer of a core quantum dot, and may also be a surface layer of a shell structure of a quantum dot with a core/shell structure) by means of diffusion and permeation; after the metal ion is coordinated with the negative ion of the quantum dot surface layer, an oxidation reaction is further occurred to oxidize the metal ion into an oxide molecule; finally, the oxide molecule is externally growth at the quantum dot to form an oxide layer which half covers the surface of the quantum dot. By introducing the oxide layer that partly covers the surface of the quantum dot and is combined with the negative ion of the quantum dot surface layer onto the surface of the quantum dot, the negative ion (e.g., S ion, Se ion, Te ion, P ion and the like) of the quantum dot surface layer can be protected, so as to prevent the negative ion of the quantum dot surface layer from oxidation, to passivate the surface of the quantum dot, and to isolate the quantum dot from external moisture and oxygen. In this way, the manufacturing method of the quantum dot structure can improve the optical stability and the chemical stability of the quantum dot under the preconditions that the optical property and surface ligand of the quantum dot will not be changed. The manufacturing method of the quantum dot structure can also maintain an initial fluorescence quantum yield of the quantum dot. Moreover, in the quantum dot structure manufactured by the manufacturing method of the quantum dot structure, the oxide layer can also occupy the surface dangling bond of the negative ion (e.g., S, Se or the like) of the quantum dot surface layer, and eliminate the surface defect of the quantum dot, so as to further improve the fluorescence quantum yield of the quantum dot.

On the other aspect, the manufacturing method of the quantum dot structure introduces the oxide layer that half covers the quantum dot surface layer by adopting a chemical solution method, which possesses advantages of low cost, convenient operation and the like. Furthermore, the excessive, unreacted oxide precursor in the reaction solution can be represented through instruments. Although chemical vapor deposition (CVD) method and physical vapor deposition (PVD) method, etc., may be used for forming the oxide layer, what is formed is an oxide atom layer completely covering the entire surface of the quantum dot; furthermore, apparatuses for chemical vapor deposition (CVD) method and physical vapor deposition (PVD) method involve complicated operation and expensive cost.

For example, in some examples, attaching the metal ion in the oxide precursor solution onto the surface of the quantum dot includes: attaching the metal ion in the oxide precursor solution onto the surface of the quantum dot by at least one of a heating process, a stirring process, and an ultrasonic process.

For example, in some examples, attaching the metal ion in the oxide precursor solution onto the surface of the quantum dot by at least one of a heating process, a stirring process, and an ultrasonic process includes: performing the heating process and the stirring process to a mixed solution of the solution of quantum dot and the oxide precursor solution to cause the metal ion in the oxide precursor solution to be attached onto the surface of the quantum dot; a temperature of the heating process is 200° C.-300° C., and a revolving speed of the stirring process is 300 rpm-1000 rpm.

For example, in some examples, the oxide precursor solution includes a long chain fatty acid salt of at least one selected from the group consisting of cadmium (Cd) ion, nickel (Ni) ion, zinc (Zn) ion, aluminum (Al) ion, and rare earth ion.

An embodiment of the present disclosure further provides a manufacturing method of an optical film. The manufacturing method of the optical film includes: manufacturing at least one of a red color quantum dot, a green color quantum dot and a blue color quantum dot by adopting the above-described manufacturing method of the quantum dot structure; mixing a solution of at least one of the manufactured red color quantum dot, the manufactured green color quantum dot and the manufactured blue color quantum dot with a polymer solution, and pouring the mixed solution onto a polymeride substrate; and curing the polymer solution to form the optical film.

For example, in some examples, the solution of at least one of the red color quantum dot, the green color quantum dot and the blue color quantum dot includes a low boiling point solvent. The low boiling point solvent refers to a good solvent capable of dissolving the quantum dot, for example, methylbenzene, chloroform, n-hexane, n-heptane, n-octane and the like.

For example, in some examples, the manufacturing method of the optical film further includes: precipitating at least one of the red color quantum dot, the green color quantum dot and the blue color quantum dot manufactured by adopting the above-described manufacturing method of the quantum dot structure by using methylbenzene-ethyl alcohol, and then dissolving the same into a methylbenzene solution.

For example, mixing at least one of the red color quantum dot, the green color quantum dot and the blue color quantum dot at an amount of 10⁻⁵ mmol with 1 mL methylbenzene solution.

For example, in some examples, the above-mentioned polymer solution includes acrylic resin.

For example, in some examples, the above-mentioned polymeride substrate includes polyethylene terephthalate. The polyethylene terephthalate may be prepared by steps including: performing an esterification to a phthalic acid solution and an ethylene glycol solution to generate di-hydroxyethyl terephthalate (BHET); and further performing a condensation polymerization to the di-hydroxyethyl terephthalate to finally obtain the polyethylene terephthalate.

For example, mixing a solution of at least one of the manufactured red color quantum dot, the manufactured green color quantum dot and the manufactured blue color quantum dot with a polymer solution and pouring the mixed solution onto a polymeride substrate may include: mixing a 10⁻⁵ mmol solution of at least one of the red color quantum dot as manufactured, the green color quantum dot as manufactured, and the blue color quantum dot as manufactured with 1 mL methylbenzene solution, and then with 10 g acrylic resin; subsequently, transferring the above-described solution(s) into a polymeride substrate of polyethylene terephthalate.

FIG. 7 is a schematic view illustrating steps of a manufacturing method of an optical film provided by an embodiment of the present disclosure. As illustrated in FIG. 7, firstly, mixing a solution of the above-described quantum dot structure with a polymer solution; then pouring the mixed solution onto a polymeride substrate; and then irradiating the polymeride substrate with ultraviolet (UR) light to form an optical film on the polymeride substrate.

For example, in some examples, curing the polymer solution to form the optical film includes: UV curing the polymer solution to form the optical film. For example, irradiating for 30 min-90 min by adopting UR light of 365 nm to obtain a cross-linked optical film.

For the disclosure, the following statements should be noted:

(1) The accompanying drawings involve only the structure(s) in connection with the embodiment(s) of the present disclosure, and other structure(s) can be referred to common design(s).

(2) In case of no conflict, the embodiments of the present disclosure and the features in the embodiments can be combined with each other to obtain new embodiments.

What have been described above are only specific implementations of the present disclosure, the protection scope of the present disclosure is not limited thereto. Any changes or substitutions easily occur to those skilled in the art within the technical scope of the present disclosure should be covered in the protection scope of the present disclosure. Therefore, the protection scope of the present disclosure should be based on the protection scope of the claims.

1. A quantum dot structure, comprising:
a quantum dot, comprising a quantum dot body and a quantum dot surface layer; and
an oxide layer on a surface of the quantum dot, the oxide layer partly covering the surface of the quantum dot,
wherein the quantum dot surface layer comprises a negative ion, and the oxide layer is combined with the negative ion through a coordinate bond.

2. The quantum dot structure according to claim 1, wherein the oxide layer comprises a metal ion.

3. The quantum dot structure according to claim 2, wherein the metal ion comprises at least one selected from the group consisting of cadmium (Cd) ion, nickel (Ni) ion, zinc (Zn) ion, aluminum (Al) ion, and rare earth ion.

4. The quantum dot structure according to claim 2, wherein one negative ion is combined with one metal ion.

5. The quantum dot structure according to claim 1, wherein a thickness of the oxide layer is in a range of 0.3 nm-1 nm.

6. The quantum dot structure according to claim 1, wherein the quantum dot surface layer further comprises a positive ion, and
the positive ion and the negative ion are regularly arranged on the quantum dot surface layer.

7. The quantum dot structure according to claim 5, wherein the oxide layer exposes the positive ion.

8. The quantum dot structure according to claim 6, further comprising:
a surface ligand on the positive ion of the quantum dot and on the oxide layer.

9. The quantum dot structure according to claim 1, wherein a diameter of the quantum dot is in a range of 3 nm-15 nm.

10. The quantum dot structure according to claim 1, wherein the quantum dot comprises one or more selected from the group consisting of a core quantum dot, a core/shell quantum dot, a core/shell/shell quantum dot, and a core/gradient shell layer quantum dot.

11. An optical film, comprising the quantum dot structure according to claim 1.

12. A display device, comprising a light-emitting region, wherein the light-emitting region is provided with the quantum dot structure according to claim 1 or the optical film according to claim 11.

13. A manufacturing method of a quantum dot structure, comprising:
providing a quantum dot, the quantum dot comprising a quantum dot body and a quantum dot surface layer; and
forming an oxide layer on a surface of the quantum dot to partly cover the surface of the quantum dot,
wherein the quantum dot surface layer comprises a negative ion, and the oxide layer is combined with the negative ion through a coordinate bond.

14. The manufacturing method of the quantum dot structure according to claim 13, wherein forming the oxide layer on the surface of the quantum dot to partly cover the surface of the quantum dot comprises:
mixing a solution of the quantum dot with a solution containing a metal ion;
attaching the metal ion in the solution containing the metal ion onto the surface of the quantum dot;
introducing oxygen gas and driving the metal ion in the solution containing the metal ion to be oxidized on the surface of the quantum dot and to generate an oxide molecule; and
forming the oxide layer on the surface of the quantum dot by controlling an amount of the solution containing the metal ion and controlling a reaction time.

15. The manufacturing method of the quantum dot structure according to claim 14, wherein attaching the metal ion in the solution containing the metal ion onto the surface of the quantum dot comprises:
attaching the metal ion in the solution containing the metal ion onto the surface of the quantum dot by at least one of a heating process, a stirring process, and an ultrasonic process.

16. The manufacturing method of the quantum dot structure according to claim 15, wherein attaching the metal ion in the solution containing the metal ion onto the surface of the quantum dot by at least one of a heating process, a stirring process, and an ultrasonic process comprises:
performing the heating process and the stirring process to a mixed solution of the solution of the quantum dot and the solution containing the metal ion to cause the metal ion in the solution containing the metal ion to be attached onto the surface of the quantum dot,
wherein a temperature of the heating process is in a range of 200° C.-300° C., and a revolving speed of the stirring process is in a range of 300 rpm-1000 rpm.

17. The manufacturing method of the quantum dot structure according to claim 13, wherein the solution containing the metal ion comprises a long chain fatty acid salt of at least one selected from the group consisting of cadmium (Cd) ion, nickel (Ni) ion, zinc (Zn) ion, aluminum (Al) ion, and rare earth ion.

18. A manufacturing method of an optical film, comprising:
manufacturing at least one of a red color quantum dot, a green color quantum dot, and a blue color quantum dot by adopting the manufacturing method of the quantum dot structure according to claim 13;
mixing a solution of at least one of the red color quantum dot as manufactured, the green color quantum dot as manufactured, and the blue color quantum dot as manufactured with a polymer solution, and pouring the mixed solution onto a polymeride substrate; and
curing the polymer solution to form the optical film.
